(19) United States
(12) Patent Application Publication
(10) Pub. No.: US 2015/0162170 A1
(43) Pub. Date: Jun. 11, 2015

(54) PLASMA PROCESSING APPARATUS AND FOCUS RING

(71) Applicant: TOKYO ELECTRON LIMITED, Tokyo (JP)

(72) Inventors: Hiroki KISHI, Kurokawa-gun (JP); Masaaki MIYAGAWA, Kurokawa-gun (JP); Toshinori KITABATA, Kurokawa-gun (JP); Manabu IWATA, Kurokawa-gun (JP)

(21) Appl. No.: 14/564,371

(22) Filed: Dec. 9, 2014

(30) Foreign Application Priority Data
Dec. 10, 2013 (JP) 2013-255427

(51) Int. Cl. H01J 37/32

(52) U.S. Cl. CPC H01J 37/32642; H01J 37/32009; H01J 37/32715

(57) ABSTRACT

A degree of tilting caused by consumption of a focus ring can be suppressed. A plasma processing apparatus includes a chamber configured to perform a plasma process on a target object; a mounting table which is provided within the chamber and has a mounting surface on which the target object is mounted; and the focus ring, provided on the mounting table to surround the target object mounted on the mounting surface, having a first flat portion lower than the mounting surface, a second flat portion higher than the first flat portion and not higher than a target surface of the target object, and a third flat portion higher than the second flat portion and the target surface of the target object in sequence from an inner peripheral side thereof to an outer peripheral side thereof.

### CROSS-REFERENCE TO RELATED APPLICATION

This application claims the benefit of Japanese Patent Application No. 2013-255427 filed on Dec. 10, 2013, the entire disclosures of which are incorporated herein by reference.

### TECHNICAL FIELD

The embodiments described herein pertain generally to a plasma processing apparatus and a focus ring.

### BACKGROUND

Conventionally, in a plasma processing apparatus, a target object is mounted on a mounting table provided within a chamber. At the mounting table, a focusing ring is provided to surround the target object mounted on a mounting surface. By way of example, there has been known a focus ring in which a first flat portion lower than the mounting surface of the mounting table and a second flat portion higher than the first flat portion and a target surface of the target object are formed in sequence from an inner peripheral side thereof to an outer peripheral side thereof.

Patent Document 1: Japanese Registered Utility Model Publication No. 3166974

However, in the above-described conventional technology, it is not considered to suppress a degree of tilting caused by consumption of the focus ring. Here, the tilting refers to a phenomenon where a hole shape formed on the target surface of the target object becomes inclined when the target object is plasma-processed.

By way of example, in the above-described conventional technology, if the focus ring is consumed by plasma, there is a change in height difference between a plasma sheath formed above the focus ring and a plasma sheath formed above the target object. For this reason, an incident direction of an ion into the target object is changed, so that the titling progresses. In other words, a variation in inclination of the hole shape formed on the target surface of the target object is increased as the focus ring is further consumed, which hinders the inclination of the hole shape formed on the target surface of the target object from satisfying a specification set to be allowable in advance.

### SUMMARY

In one example embodiment, a plasma processing apparatus includes a chamber configured to perform a plasma process on a target object; a mounting table which is provided within the chamber and has a mounting surface on which the target object is mounted; and a focus ring, provided on the mounting table to surround the target object mounted on the mounting surface, having a first flat portion lower than the mounting surface; a second flat portion higher than the first flat portion and not higher than a target surface of the target object; and a third flat portion higher than the second flat portion and the target surface of the target object in sequence from an inner peripheral side thereof to an outer peripheral side thereof.

In the example embodiment, a plasma processing apparatus includes a chamber configured to perform a plasma process on a target object; a mounting table which is provided within the chamber and has a mounting surface on which the target object is mounted; and a focus ring, provided on the mounting table to surround the target object mounted on the mounting surface, having a first flat portion lower than the mounting surface; a second flat portion higher than the first flat portion and not higher than a target surface of the target object; and a third flat portion higher than the second flat portion and the target surface of the target object in sequence from an inner peripheral side thereof to an outer peripheral side thereof.

A diameter of a circle, which is formed by an end of the third flat portion at the inner peripheral side of the focus, may be in a range of 315 mm or more to 325 mm or less.

A height position of the second flat portion with respect to the target surface of the target object may be set to be in a range of from a position 1 mm lower than the target surface of the target object to a position of the target surface of the target object.

A height position of the third flat portion with respect to the target surface of the target object may be set to be in a range of from a position 3 mm higher than the target surface of the target object to a position 5 mm higher than the target surface of the target object.

An inclined portion may be formed between the second flat portion and the third flat portion.

The first flat portion, the second flat portion, the third flat portion, and a fourth flat portion that is lower than the third flat portion and higher than the target surface of the target object may be formed in the focus ring in sequence from the inner peripheral side thereof to the outer peripheral side thereof.

The mounting table may include an electrostatic chuck configured to adsorb the target object mounted on the mounting surface, and a recess may be formed at a region on a bottom surface of the focus ring, which is located at an outer side than the electrostatic chuck in a radial direction of the focus ring and may be opposite to a surface on which the first flat portion, the second flat portion and the third flat portion are formed.

In accordance with the example embodiment, the plasma processing apparatus has an effect of suppressing a degree of tilting caused by consumption of the focus ring.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a cross-sectional view schematically illustrating an overall configuration of a plasma processing apparatus (etching apparatus) in accordance with a first example embodiment;

FIG. 2 is a schematic cross-sectional view illustrating a positional relationship among a focus ring, a semiconductor wafer, an electrostatic chuck, and a mounting table in accordance with the first example embodiment;

FIG. 3A and FIG. 3B are explanatory diagrams illustrating a change in a plasma sheath caused by the consumption of a conventional focus ring;

FIG. 4A and FIG. 4B are explanatory diagrams illustrating a change in a plasma sheath caused by the consumption of the focus ring in accordance with the first example embodiment;

FIG. 5 is a diagram illustrating a relationship between a diameter X and a consumption sensitivity;

FIG. 6 is a diagram illustrating a relationship between a position Y2 and an initial tilting angle; and

FIG. 7 is a diagram illustrating an example of a relationship between a usage time of the focus ring and the tilting angle in accordance with the first example embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, an example embodiment of a plasma processing apparatus and a focus ring will be explained in detail with reference to the accompanying drawings. Further, the present example embodiment does not limit the disclosure to be disclosed herein. Example embodiments can be combined as appropriate within a range where the content of the process is not contradicted.

### First Example Embodiment

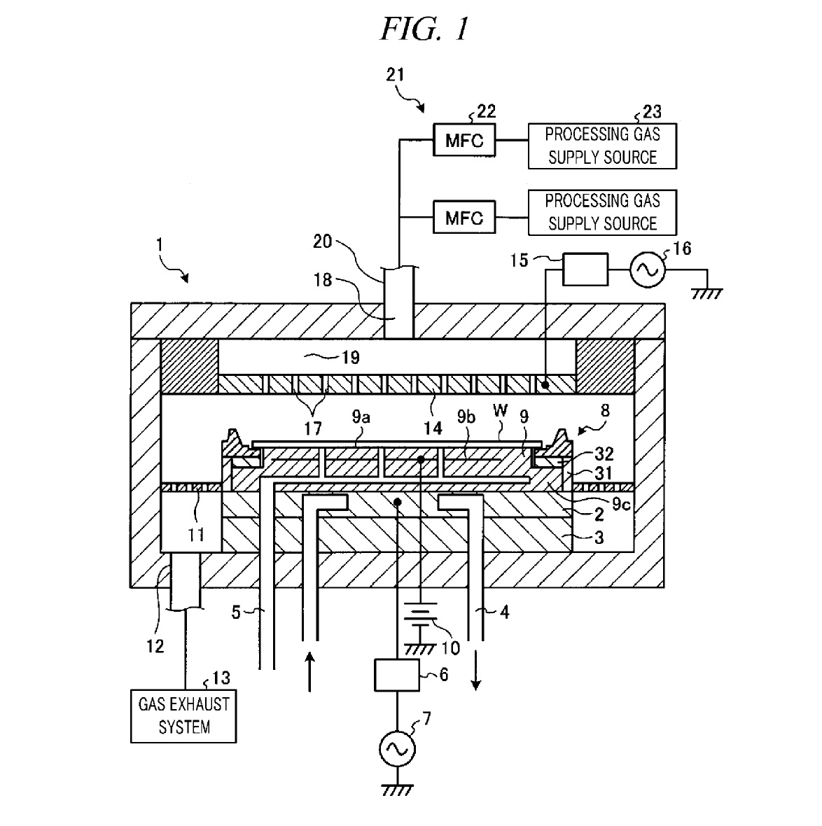

FIG. 1 is a cross-sectional view schematically illustrating an overall configuration of a plasma processing apparatus (etching apparatus) in accordance with the first example embodiment. As depicted in FIG. 1, the plasma processing apparatus and includes a cylindrical chamber 1 which constitutes a processing chamber and is made of, for example, aluminum or the like and configured to airtightly close the inside thereof.

Within the chamber 1, there is provided a mounting table 2 which is formed of a conductive material, such as aluminum or the like, in a block shape and also serves as a lower electrode.

The mounting table 2 is supported within the chamber 1 via an insulating plate 3 made of ceramic or the like. The mounting table 2 has a mounting surface on which a semiconductor wafer W as a target object is mounted. On the mounting surface of the mounting table 2, there is provided an electrostatic chuck 9 configured to adsorb the semiconductor wafer W. The electrostatic chuck 9 is an insulator in which an electrode 9b connected to a DC power supply 10 is embedded. The electrostatic chuck 9 is configured to adsorb and hold the semiconductor wafer W by a Coulomb force generated by a DC voltage to be applied from the DC power supply 10 to the electrode 9b. An upper surface of the electrostatic chuck 9 includes a holding surface 9a for holding the semiconductor wafer W; and a peripheral portion 9c relatively lower than the holding surface 9a. On an outer side surface of the peripheral portion 9c of the electrostatic chuck 9, an insulating member 31 made of, for example, quartz or the like is arranged, and on an upper surface of the peripheral portion 9c of the electrostatic chuck 9, a conductive member 32 made of, for example, aluminum or the like is arranged. Further, on the holding surface 9a of the electrostatic chuck 9, the semiconductor wafer W is mounted. That is, the holding surface 9a of the electrostatic chuck 9 corresponds to the mounting surface of the mounting table 2, and the insulating member 31 and the conductive member 32 correspond to a non-mounting surface of the mounting table 2. Therefore, hereinafter, the electrostatic chuck 9, the insulating member 31, the conductive member 32, and the mounting table 2 will be collectively referred to as “the mounting table 2” as appropriate, and the mounting surface of the mounting table 2 will be referred to as “the holding surface 9a of the electrostatic chuck 9” as appropriate.

Further, within the mounting table 2, a heat transfer medium path 4 through which an insulating fluid as a heat transfer medium for temperature control is circulated and a gas path 5 through which a gas, such as a helium gas, for temperature control is supplied to a rear surface of the semiconductor wafer W are provided.

Furthermore, the insulating fluid controlled to a preset temperature is circulated in the heat transfer medium path 4 to control the mounting table to a preset temperature, and the gas for temperature control is supplied between the mounting table 2 and the rear surface of the semiconductor wafer W through the gas path 5 to promote the heat exchange therebetween and control the semiconductor wafer W to a preset temperature with high accuracy and high efficiency.

The mounting table 2 is connected to a high frequency power supply (RF power supply) 7 via a matching unit 6, and a high frequency power of a preset frequency is supplied to the mounting table 2 from the high frequency power supply 7.

Further, as depicted in FIG. 1, the plasma processing apparatus includes a focus ring 8 provided at the mounting table 2 to surround the semiconductor wafer W mounted on the mounting surface of the mounting table 2, i.e., the holding surface 9a of the electrostatic chuck 9. The focus ring 8 is a ring-shaped member made of a conductive material such as silicon, carbon, SiC, or the like.

Further, outside the focus ring 8, there is provided a gas exhaust ring 11 which is annularly formed and includes multiple gas exhaust holes. A processing space within the chamber 1 is evacuated by a vacuum pump or the like of a gas exhaust system 13 connected to a gas exhaust port 12 via the gas exhaust ring 11.

Meanwhile, at a ceiling wall of the chamber 1 above the mounting table 2, a shower head 14 is provided to face the mounting table 2 in parallel with each other. The mounting table 2 and the shower head 14 are configured to serve as a pair of electrodes (a lower electrode and an upper electrode). Further, the shower head 14 is connected to a high frequency power supply 16 via a matching unit 15.

The shower head 14 includes multiple gas discharge holes 17 at a bottom surface thereof, and includes a gas inlet opening 18 at its upper portion. Further, within the shower head 14, a gas diffusion space 19 is formed. The gas inlet opening 18 is connected to a gas supply line 20, and the other end of the gas supply line 20 is connected to a gas supply system 21. The gas supply system 21 includes a mass flow controller (MFC) 22 configured to control a gas flow rate and a processing gas supply source 23 configured to supply, for example, a processing gas for etching or the like.

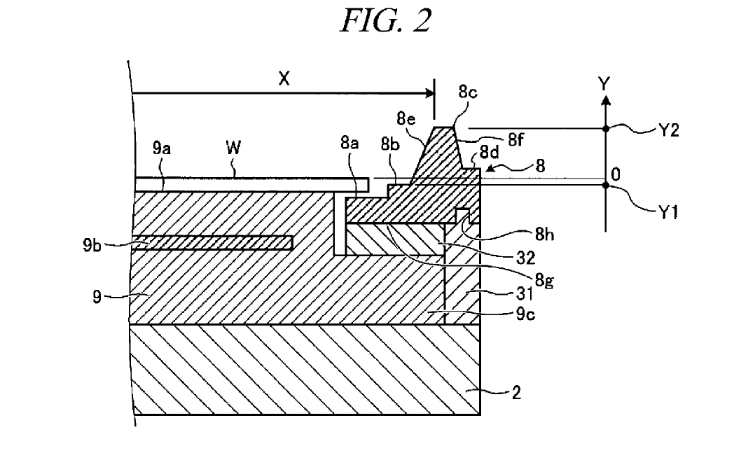

Hereinafter, referring to FIG. 2, the focus ring 8 depicted in FIG. 1 will be further explained. FIG. 2 is a schematic cross-sectional view illustrating a positional relationship among the focus ring, the semiconductor wafer, the electrostatic chuck, and the mounting table in accordance with the first example embodiment.

As depicted in FIG. 2, in the focus ring 8, a first flat portion 8a, a second flat portion 8b, a third flat portion 8c, and a fourth flat portion 8d are formed in sequence from the inner peripheral side thereof to the outer peripheral side thereof. The first flat portion 8a is lower than the mounting surface of the mounting table 2, i.e., the holding surface 9a of the electrostatic chuck 9. The second flat portion 8b is higher than the first flat portion 8a and not higher than the target surface of the semiconductor wafer W. The third flat portion 8c is higher than the second flat portion 8b and the semiconductor wafer W. Further, in an example depicted in FIG. 2, the fourth flat portion 8d is formed, but this is not limited thereto. The fourth flat portion 8d may not be formed.

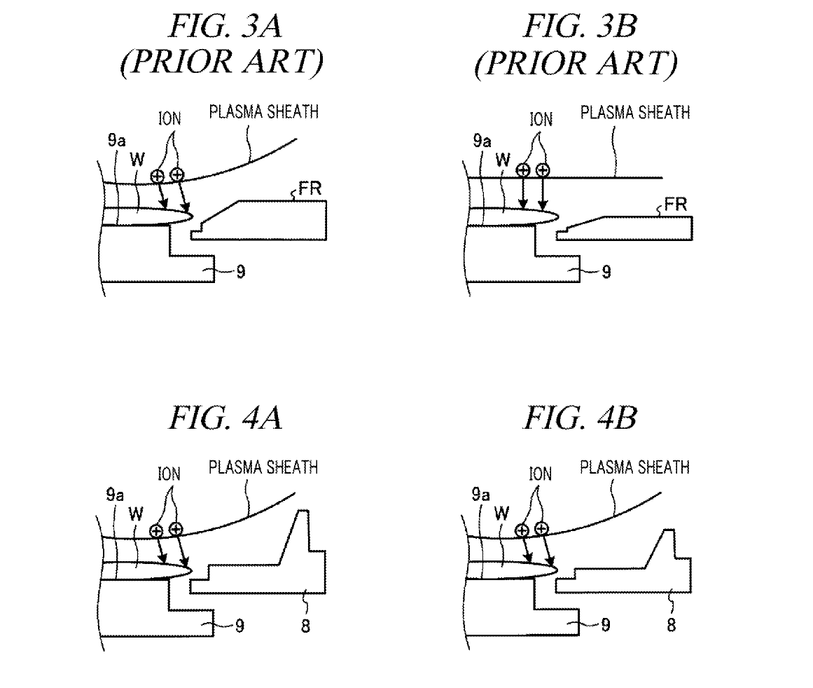

Hereinafter, the reason why the first flat portion 8a, the second flat portion 8b, and the third flat portion 8c are formed in the focus ring 8 will be explained by comparison between the conventional focus ring and the focus ring 8. FIG. 3A and FIG. 3B are explanatory diagrams illustrating a change in a plasma sheath caused by consumption of the conventional focus ring. FIG. 4A and FIG. 4B are explanatory diagrams illustrating a change in a plasma sheath caused by consumption of the focus ring in accordance with the first example embodiment. Further, in a focus ring FR depicted in FIG. 3A and FIG. 3B, a first flat portion lower than a mounting surface of the mounting table, i.e., the holding surface 9a of the electrostatic chuck 9 and a second flat portion higher than the first flat portion and the target surface of the semiconductor wafer W are formed in sequence from an inner peripheral side thereof to an outer peripheral side thereof.

Referring to FIG. 3A and FIG. 3B, the conventional focus ring FR will be explained first. If the focus ring FR is a new product, as depicted in FIG. 3A, a plasma sheath formed above the focus ring FR is higher than a plasma sheath formed above the semiconductor wafer W. In this case, ions in the plasma are slantly incident from a central portion of the target surface of the semiconductor wafer W toward a peripheral portion thereof. As a result, a hole shape formed on the target surface of the semiconductor wafer W is inclined slantly toward the peripheral portion of the target surface of the semiconductor wafer W with respect to a vertical direction.

If the focus ring FR is consumed by the plasma, a height of the focus ring FR decreases. Then, as depicted in FIG. 3B, a height of the plasma sheath formed above the focus ring FR decreases, so that the height of the plasma sheath formed above the focus ring FR becomes equal to the height of the plasma sheath formed above the semiconductor wafer W. That is, when the focus ring FR is consumed, there is a change in the height difference between the plasma sheath formed above the focus ring FR and the plasma sheath formed above the semiconductor wafer W. In this case, ions in the plasma are incident perpendicularly to the target surface of the semiconductor wafer W. As a result, the hole shape formed on the target surface of the semiconductor wafer W becomes perpendicular to the target surface of the semiconductor wafer W. That is, in the case of using the conventional focus ring FR, a degree of tilting caused by the consumption of the focus ring FR is increased.

Meanwhile, referring to FIG. 4A and FIG. 4B, the focus ring 8 in accordance with the first example embodiment will be explained. If the focus ring 8 is a new product, as depicted in FIG. 4A, a plasma sheath formed above the focus ring 8 is higher than a plasma sheath formed above the semiconductor wafer W. In this case, ions in the plasma are slantly incident toward the peripheral portion of the target surface of the semiconductor wafer W. As a result, a hole shape formed on the target surface of the semiconductor wafer W is inclined slantly toward the peripheral portion of the target surface of the semiconductor wafer W from the vertical direction.

If the focus ring 8 is consumed by the plasma, a height of the focus ring 8 decreases. However, since the focus ring 8 includes the first flat portion 8a, the second flat portion 8b, and the third flat portion 8c, a change in height of the plasma sheath formed above the focus ring 8 is suppressed. In particular, as depicted in FIG. 4B, a decrease in height of the plasma sheath formed above the focus ring 8 is suppressed by the third flat portion 8c. Therefore, a height difference between the plasma sheath formed above the focus ring 8 and the plasma sheath formed above the semiconductor wafer W is hardly changed. In this case, ions in the plasma are slantly incident from the central portion of the target surface of the semiconductor wafer W toward the peripheral portion thereof. As a result, the hole shape formed on the target surface of the semiconductor wafer W is slantly inclined toward the peripheral portion of the target surface of the semiconductor wafer W with respect to the vertical direction. That is, in the case of using the focus ring 8, the tilting caused by the consumption of the focus ring 8 can be more slowly progressed. Therefore, in the first example embodiment, in order to suppress the degree of tilting caused by the consumption of the focus ring 8, the first flat portion 8a, the second flat portion 8b, and the third flat portion 8c are formed in the focus ring 8.

Returning to FIG. 2, a diameter X of a circle, which is formed by an end of the third flat portion 8c at the inner peripheral side of the focus 8, is in a range of desirably 315 mm or more to 325 mm or less, and more desirably 317 mm or more to 323 mm or less.

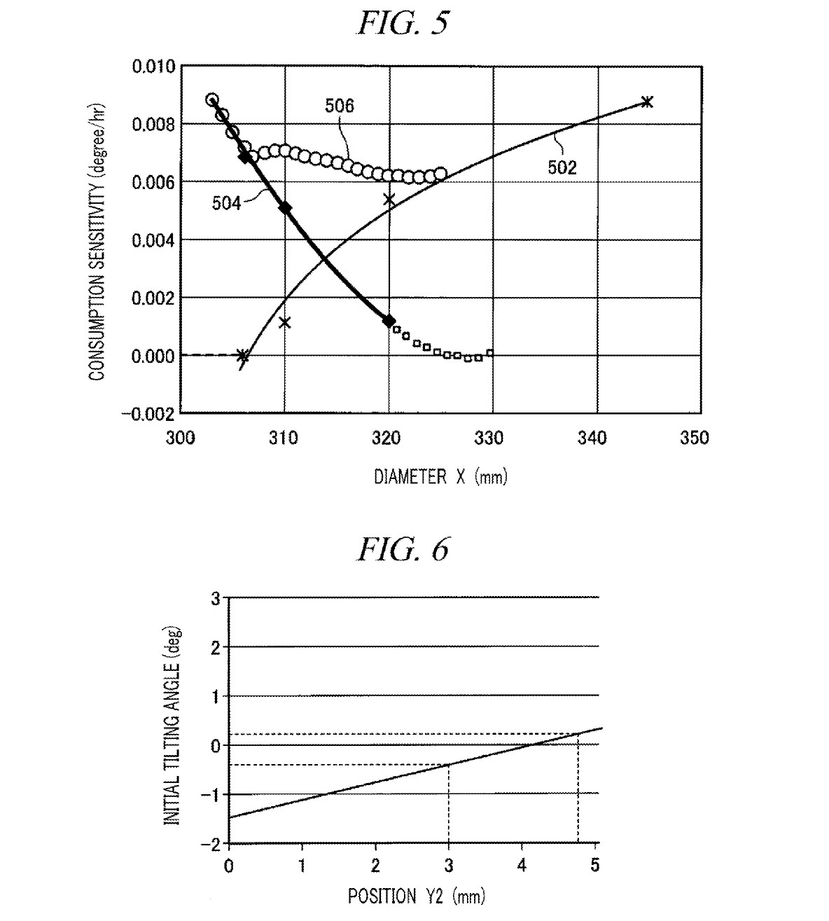

FIG. 5 is a diagram illustrating a relationship between a diameter X and a consumption sensitivity. In FIG. 5, a horizontal axis represents the diameter X (mm) of the circle, which is formed by an end of the third flat portion 8c at the inner peripheral side of the focus 8, and a longitudinal axis represents a consumption sensitivity (degree/hr). The consumption sensitivity refers to a variation of an inclination of a hole shape formed on a target surface of a target object, and more specifically, refers to an inclination degree of the hole shape formed on the target surface of the target object with respect to a vertical direction while a focus ring is exposed to plasma for 1 hour. The consumption sensitivity is increased as the focus ring is further consumed. That is, as a value of the consumption sensitivity is increased, a degree of tilting caused by the consumption of the focus ring is increased.

A graph 502 in FIG. 5 shows a consumption sensitivity of the semiconductor wafer W assuming that only the second flat portion 8b of the multiple flat portions of the focus ring 8 is exposed to plasma. Further, a graph 504 shows a consumption sensitivity of the semiconductor wafer W assuming that only the third flat portion 8c of the multiple flat portions of the focus ring 8 is exposed to plasma. Furthermore, a graph 506 shows a total value (hereinafter, referred to as “consumption sensitivity total value”) of the consumption sensitivity of the semiconductor wafer W shown in the graph 502 and the consumption sensitivity of the semiconductor wafer W shown in the graph 504.

As shown in FIG. 5, the consumption sensitivity total value is decreased to 0.006 (degree/hr) to 0.0065 (degree/hr) when the diameter X is in a range of 315 mm or more to 325 mm or less. Further, the consumption sensitivity total value is decreased to 0.006 (degree/hr) to 0.0063 (degree/hr) when the diameter X is in a range of 317 mm or more to 323 mm or less. Furthermore, the consumption sensitivity total value is the lowest when the diameter X is 320 mm. Thus, in the focus ring 8 in accordance with the first example embodiment, the diameter X is set to be in a range of 315 mm or more to 325 mm or less, and more desirably, 317 mm or more to 323 mm or less. In other words, the diameter X of the circle, which is formed by an end of the third flat portion 8c at the inner peripheral side of the focus 8, is set such that the consumption sensitivity total value can be equal to or lower than a preset value (for example, 0.0065 (degree/hr)).

Returning back to FIG. 2, a height position Y1 of the second flat portion 8b with respect to the target surface of the semiconductor wafer W is set to be in a range of from a position 1 mm lower than the target surface of the semiconductor wafer W to a position of the target surface of the semiconductor wafer W. In the example depicted in FIG. 2, if a Y axis is set from the reference point on the target surface of the semiconductor wafer W to a vertically upward direction, the height position Y1 of the second flat portion 8b with respect to the target surface of the semiconductor wafer W is set to be in a range of −1 (mm)≦Y≦0 (mm). This is because if the position Y1 is set to be in a range of Y<−1, a reaction product generated during a plasma reaction may be attached to the opposite surface of the target surface of the semiconductor wafer W and if the position Y1 is set to be in a range of Y>0, a plasma sheath is greatly changed.

Further, a height position Y2 of the third flat portion 8c with respect to the target surface of the semiconductor wafer W is set to be in a range of from a position 3 mm higher than the target surface of the semiconductor wafer W to a position 5 mm higher than the target surface of the semiconductor wafer W. In the example depicted in FIG. 2, if the Y axis is set from the reference point on the target surface of the semiconductor wafer W to the vertically upward direction, the height position Y2 of the third flat portion 8c with respect to the target surface of the semiconductor wafer W is set to be in a range of 3 (mm)≦Y≦5 (mm).

FIG. 6 is a diagram illustrating a relationship between the position Y2 and an initial tilting angle. In FIG. 6, a horizontal axis represents the height position Y2 (mm) of the third flat portion 8c with respect to the target surface of the semiconductor wafer W and a longitudinal axis represents the initial tilting angle (degree). The initial tilting angle refers to an inclination degree of a hole shape formed on a target surface of a target object with respect to a vertical direction when the target object is plasma-processed using the focus ring 8 as a new product. A sign of the initial tilting angle becomes positive when the hole shape formed on the target surface of the target object is inclined slantly toward a central portion of the target object with respect to the vertical direction. On the other hand, a sign of the initial tilting angle becomes negative when the hole shape formed on the target surface of the target object is inclined slantly toward a peripheral portion of the target object with respect to the vertical direction. Desirably, the initial tilting angle is in a range of, for example, −1.35 (degree) or more to 0.35 (degree) or less.

As depicted in FIG. 6, the initial tilting angle is in a range of −1.35 (degree) or more to 0.35 (degree) or less when the position Y2 is in a range of 3 mm or more to 5 mm or less. Thus, in the focus ring 8 in accordance with the first example embodiment, the position Y2 is set to be in a range of 3 (mm)≦Y≦5 (mm).

Returning to FIG. 2, an inclined portion 8e is formed between the second flat portion 8b and the third flat portion 8c. Herein, a configuration in which a corner portion is formed between the second flat portion 8b and the third flat portion 8c instead of the inclined portion may be taken into consideration. However, in the configuration in which the corner portion is formed between the second flat portion 8b and the third flat portion 8c, there may be a rapid change in a plasma sheath above the corner portion. As a result, a surface of the corner portion may be rough due to the plasma or various deposits may be attached to the corner portion. Therefore, in the first example embodiment, for the purpose of avoiding generation of surface roughness or attachment of deposits, the inclined portion 8e is formed between the second flat portion 8b and the third flat portion 8c.

The fourth flat portion 8d is lower than the third flat portion 8c and higher than the target surface of the semiconductor wafer W. To be specific, a height of the fourth flat portion 8d is set to be a preset height from a bottom surface 8g on the opposite side of a surface, on which the first flat portion 8a, the second flat portion 8b, the third flat portion 8c, and the fourth flat portion 8d are formed, among the surfaces of the focus ring 8. The preset height is determined in advance such that a gap between the shower head 14 serving as the upper electrode and the focus ring 8 does not change a peak-to-peak voltage Vpp of the focus ring 8. By way of example, the preset height may be set to be 5.5 mm.

An inclined portion 8f is formed between the fourth flat portion 8d and the third flat portion 8c. Herein, a configuration in which a corner portion is formed between the fourth flat portion 8d and the third flat portion 8c instead of the inclined portion may be taken into consideration. However, in the configuration in which the corner portion is formed between the fourth flat portion 8d and the third flat portion 8c, there may be a rapid change in a plasma sheath above the corner portion. As a result, a surface of the corner portion may be rough due to the plasma or various deposits may be attached to the corner portion. Therefore, in the first example embodiment, for the purpose of avoiding generation of surface roughness or attachment of deposits, the inclined portion 8f is formed between the fourth flat portion 8d and the third flat portion 8c.

Further, a recess 8h is formed at a region on the bottom surface 8g of the focus ring 8, which is located at a side outer than the electrostatic chuck 9 in a radial direction of the focus ring 8. The recess 8h serves as a labyrinth that suppresses plasma from being introduced toward the electrostatic chuck 9. In the recess 8h, a part of the insulating member 31 of the mounting table 2 is insertion-fitted.

As described above, the plasma processing apparatus in accordance with the first example embodiment includes the chamber 1 configured to perform a plasma process to the target object; the mounting table 2 which is provided within the chamber 1 and has the mounting surface on which the target object is mounted; and the focus ring 8 which is provided on the mounting table 2 to surround the target object mounted on the mounting surface. Further, in the focus ring 8, the first flat portion 8a lower than the mounting surface of the mounting table 2, the second flat portion 8b higher than the first flat portion 8a and not higher than a target surface of the target object, and the third flat portion 8c higher than the second flat portion 8b and the target surface of the target object are formed in sequence from the inner peripheral side thereof to the outer peripheral side thereof. As a result, it is possible to suppress the degree of tilting caused by the consumption of the focus ring 8.

There is known a two-step focus ring in which a first flat portion lower than the mounting surface of the mounting table 2 and a second flat portion higher than the first flat portion and a target surface of a target object are formed in sequence from an inner peripheral side thereof to an outer peripheral side thereof. However, in a plasma processing apparatus using the two-step focus ring, if the focus ring is consumed by plasma, there is a change in height difference between a plasma sheath formed above the focus ring and a plasma sheath formed above the target object. For this reason, an incident direction of an ion to the target object is changed, so that the titling progresses. In other words, a variation in inclination of the hole shape formed on the target surface of the target object is increased as the focus ring is further consumed, which hinders the inclination of the hole shape formed on the target surface of the target object from satisfying a specification set to be allowable in advance.

In the plasma processing apparatus in accordance with the first example embodiment, a three-step focus ring is used, as compared with the plasma processing apparatus using the two-step focus ring. That is, in the plasma processing apparatus in accordance with the first example embodiment, in the focus ring 3, the first flat portion 8a, the second flat portion 8b, and the third flat portion 8c are formed in sequence from the inner peripheral side thereof to the outer peripheral side thereof. For this reason, a change in height of the plasma sheath formed above the focus ring 8 is suppressed. In particular, a decrease in height of the plasma sheath formed above the focus ring 8 is suppressed by the third flat portion 8c. Therefore, a height difference between the plasma sheath formed above the focus ring 8 and the plasma sheath formed above the semiconductor wafer W is hardly changed. As a result, it is possible to suppress the degree of tilting caused by the consumption of the focus ring 8. Thus, the inclination of the hole shape formed on the target surface of the target object can easily satisfy the specification set to be allowable in advance, and the life of the focus ring 8 can be lengthened.

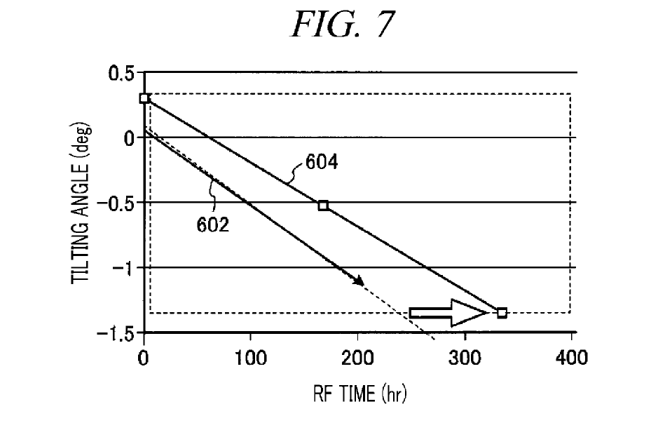

FIG. 7 is a diagram illustrating an example of a relationship between a usage time of a focus ring and a tilting angle in accordance with the first example embodiment. In FIG. 7, a horizontal axis represents a total time period during which the focus ring 8 is exposed to plasma, i.e., a usage time (hr) of the focus ring 8, and a longitudinal axis represents a tilting angle (degree). The tilting angle refers to an inclination degree of a hole shape formed on a target surface of a target object with respect to a vertical direction while the target object is plasma-processed using the focus ring 8. A sign of the tilting angle becomes positive when the hole shape formed on the target surface of the target object is inclined slantly toward a central portion of the target object with respect to the vertical direction. On the other hand, a sign of the tilting angle becomes negative when the hole shape formed on the target surface of the target object is inclined slantly toward a peripheral portion of the target object with respect to the vertical direction. In an example depicted in FIG. 7, a lower limit of the tilting angle set to be allowable in advance is −1.35 (degree).

A graph 602 in FIG. 7 shows a tilting angle in the case of using a two-step focus ring (comparative example). Further, a graph 604 shows a tilting angle in the case of using the focus ring 8 in accordance with the first example embodiment.

As depicted in FIG. 7, in the comparative example, when the tilting angle reaches −1.35 (degree) as set to be allowable in advance, a usage time of the focus ring is 250 hours. Meanwhile, in the first example embodiment, when the tilting angle reaches −1.35 (degree) as set to be allowable in advance, a usage time of the focus ring 8 is 320 hours. That is, in the first example embodiment, since the first flat portion 8a, the second flat portion 8b, and the third flat portion 8c are formed in the focus ring 8, the intercept (corresponding to the initial tilting angle) in the graph 604 can be increased and a value of the inclination (corresponding to the consumption sensitivity) in the graph 604 can be decreased. As a result, in the first example embodiment as compared with the comparative example, the life of the focus ring 8 can be increased by 70 hours.

Further, in the first example embodiment, the diameter X of a circle, which is formed by an end of the third flat portion 8c at the inner peripheral side of the focus 8, is in a range of 315 mm or more to 325 mm or less. As a result, even if the focus ring 8 is consumed, it is possible to suppress an increase in the consumption sensitivity corresponding to the variation of the inclination of the hole shape formed on the target surface of the target object.

Furthermore, in the first example embodiment, the height position of the second flat portion 8b with respect to the target surface of the target object is set to be in a range of from the position 1 mm lower than the target surface of the target object to the position of the target surface of the target object. As a result, it is possible to suppress the attachment of the reaction product generated during the plasma reaction to the opposite surface of the target surface of the semiconductor wafer W and also possible to suppress the great change in the plasma sheath.

Moreover, in the first example embodiment, the height position of the third flat portion 8c with respect to the target surface of the target object is set to be in a range of from the position 3 mm higher than the target surface of the target object to the position 5 mm higher than the target surface of the target object. As a result, it is possible to set the initial tilting angle to be in a range of the specification set to be allowable in advance.

Further, in the first example embodiment, the inclined portion 8e is formed between the second flat portion 8b and the third flat portion 8c. As a result, it is possible to avoid generation of surface roughness or attachment of deposits between the second flat portion 8b and the third flat portion 8c.

Furthermore, in the first example embodiment, the first flat portion 8a, the second flat portion 8b, the third flat portion 8c, and the fourth flat portion 8d that is lower than the third flat portion 8c and higher than the target surface of the target object are formed in the focus ring 8 in sequence from the inner peripheral side thereof to the outer peripheral side thereof. As a result, it is possible to optimize the gap between the shower head 14 serving as the upper electrode and the focus ring 8, and also possible to suppress a change in the peak-to-peak voltage Vpp of the focus ring 8.

Moreover, in the first example embodiment, the recess 8h is formed at the region on the bottom surface 8g of the focus ring 8, which is located at a side outer than the electrostatic chuck 9 in the radial direction of the focus ring 8. As a result, even if the focus ring 8 is consumed, the electrostatic chuck 9 can be appropriately protected against plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A plasma processing apparatus comprising:
a chamber configured to perform a plasma process on a target object;
a mounting table which is provided within the chamber and has a mounting surface on which the target object is mounted; and
a focus ring, provided on the mounting table to surround the target object mounted on the mounting surface, having a first flat portion lower than the mounting surface; a second flat portion higher than the first flat portion and not higher than a target surface of the target object; and a third flat portion higher than the second flat portion and the target surface of the target object in sequence from an inner peripheral side thereof to an outer peripheral side thereof.

2. The plasma processing apparatus of claim 1,
wherein a diameter of a circle, which is formed by an end of the third flat portion at the inner peripheral side of the focus, is in a range of 315 mm or more to 325 mm or less.

3. The plasma processing apparatus of claim 1,
wherein a height position of the second flat portion with respect to the target surface of the target object is set to be in a range of from a position 1 mm lower than the target surface of the target object to a position of the target surface of the target object.

4. The plasma processing apparatus of claim 1,
wherein a height position of the third flat portion with respect to the target surface of the target object is set to be in a range of from a position 3 mm higher than the target surface of the target object to a position 5 mm higher than the target surface of the target object.

5. The plasma processing apparatus of claim 1,
wherein an inclined portion is formed between the second flat portion and the third flat portion.

6. The plasma processing apparatus of claim 1,
wherein the first flat portion, the second flat portion, the third flat portion, and a fourth flat portion that is lower than the third flat portion and higher than the target surface of the target object are formed in the focus ring in sequence from the inner peripheral side thereof to the outer peripheral side thereof.

7. The plasma processing apparatus of claim 1,
wherein the mounting table includes an electrostatic chuck configured to adsorb the target object mounted on the mounting surface, and
a recess is formed at a region on a bottom surface of the focus ring, which is located at an outer side than the electrostatic chuck in a radial direction of the focus ring and is opposite to a surface on which the first flat portion, the second flat portion and the third flat portion are formed.

8. A focus ring which is provided within a chamber in which a plasma process is performed on a target object and also provided on a mounting table, which has a mounting surface on which the target object is mounted, to surround the target object mounted on the mounting surface, the focus ring comprising:
a first flat portion lower than the mounting surface;
a second flat portion that is higher than the first flat portion and not higher than a target surface of the target object; and
a third flat portion that is higher than the second flat portion and the target surface of the target object,
wherein the first flat portion, the second flat portion and the third flat portion are formed in sequence from an inner peripheral side thereof to an outer peripheral side thereof.

9. The focus ring of claim 8,
wherein a diameter of a circle, which is formed by an end of the third flat portion at the inner peripheral side of the focus ring, is in a range of 315 mm or more to 325 mm or less.

10. The focus ring of claim 8,
wherein a height position of the second flat portion with respect to the target surface of the target object is set to be in a range of from a position 1 mm lower than the target surface of the target object to a position of the target surface of the target object.

11. The focus ring of claim 8,
wherein a height position of the third flat portion with respect to the target surface of the target object is set to be in a range of from a position 3 mm higher than the target surface of the target object to a position 5 mm higher than the target surface of the target object.

12. The focus ring of claim 8,
wherein an inclined portion is formed between the second flat portion and the third flat portion.

13. The focus ring of claim 8,
wherein the first flat portion, the second flat portion, the third flat portion, and a fourth flat portion that is lower than the third flat portion and higher than the target surface of the target object are formed in sequence from the inner peripheral side thereof to the outer peripheral side thereof.

14. The focus ring of claim 8,
wherein the mounting table includes an electrostatic chuck configured to adsorb the target object mounted on the mounting surface, and
a recess is formed at a region on a bottom surface of the focus ring, which is located at an outer side than the electrostatic chuck in a radial direction of the focus ring and is opposite to a surface on which the first flat portion, the second flat portion and the third flat portion are formed.
